(19) United States
(12) Patent Application Publication
(10) Pub. No.: US 2005/0250259 A1
(43) Pub. Date: Nov. 10, 2005

(54) SOI-type semiconductor device, and production method for manufacturing such SOI-type semiconductor device

(75) Inventors: Akihito Sakakidani, Kawasaki-shi (JP); Takayuki Suzuki, Kawasaki-shi (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KAWASAKI-SHI (JP)

(21) Appl. No.: 11/080,502

(22) Filed: Mar. 16, 2005

(30) Foreign Application Priority Data
Mar. 16, 2004 (JP) 2004-075188

(51) Int. Cl. H01L 21/84

(52) U.S. Cl. 438/149; 257/347

(57) ABSTRACT

In a silicon-on-insulator (SOI)-type semiconductor device, a buried silicon dioxide layer is produced in the silicon substrate. An area of the silicon substrate, which is sited above the buried silicon dioxide layer, is defined as an SOI area, and the remaining area is defined as a non-SOI area. A peripheral edge portion of the buried silicon dioxide layer is formed as a swelling edge portion. A first field-isolation layer is formed at the SOI area along the swelling edge portion of the buried silicon dioxide layer, a second field-isolation layer is formed at the non-SOI area along the swelling edge portion of the buried silicon dioxide layer.

### BACKGROUND OF THE INVENTION

1. Field of the Invention

The present invention relates to a silicon-on-insulator (SOI)-type semiconductor device using a silicon substrate having a buried silicon dioxide layer produced therein, and a production method for manufacturing such an SOI-type semiconductor device.

2. Description of the Related Art

A silicon substrate used in an SOI-type semiconductor device is frequently referred as an SOI-substrate, and has a buried silicon dioxide layer produced therein. The production of the buried silicon dioxide layer may be carried out by using a separation-by-implanted-oxygen (SIMOX) method, as disclosed in, for example, JP-A-H10-303385. In this silicon substrate or SOI-substrate, an area of the silicon substrate, which is sited above the buried silicon dioxide layer, is defined as an SOI area, and the remaining area is defined as a non-SOI area.

In particular, in the SIMOX method, oxygen ions (O⁺) are implanted in the silicon substrate, so that the oxygen ions (O⁺) reach a given depth measured from the surface of the silicon substrate, and then the silicon substrate is subjected to an annealing process in which the implanted oxygen ions (O⁺) react with silicon atoms in the silicon substrate to thereby produce the buried silicon dioxide layer. In this case, as well-known, a peripheral edge portion of the buried silicon dioxide layer swells and becomes thicker.

The swelling of the peripheral edge portion of the buried silicon dioxide layer may cause crystalline defects in the silicon substrate in the vicinity of the swelling edge portion. When the crystalline defects are left in the silicon substrate, they may cause a leakage of current in the SOI-type semiconductor device.

In order to eliminate the crystalline defects from the silicon substrate, it is proposed that a silicon dioxide layer is formed as a field-isolation layer in the silicon substrate along a boundary between the SOI area and the non-SOI area, i.e. along the swelling edge portion of the buried silicon dioxide layer, by using a shallow-trench isolation (STI) method.

In particular, first, a trench is formed along the swelling edge portion of the buried silicon dioxide layer by using a photolithography process and a dry etching process, to thereby eliminate the crystalline defects from the silicon substrate. Then, the silicon substrate is subjected to a chemical vapor deposition (CVD) process so that the trench is filled with silicon dioxide, with a redundant silicon dioxide layer being formed on the surface of the silicon substrate. Subsequently, the redundant silicon dioxide layer is removed from the surface of the silicon substrate by using a chemical mechanical polishing (CMP) process, resulting in the formation of the field-isolation layer.

Nevertheless, voids are apt to be produced in the field-isolation layer in the vicinity of the swelling edge portion of the buried silicon oxide layer when a distance between the inner wall face of the trench and the swelling edge portion of the buried silicon oxide layer is too small, as stated in detail hereinafter. Of course, the production of the voids in the field-isolation layer should be avoided because the existence of voids results in deterioration in performance of the SOI-type semiconductor device. Namely, the void-production problem must be resolved before a good performance of the SOI-type semiconductor device can be preserved.

On the other hand, during the aforesaid dry etching process, a width of the trench becomes somewhat wider than a predetermined width dimension for the reasons stated in detail hereinafter. Of course, as miniaturization of SOI-type semiconductor devices is advanced, this trench-width problem becomes more severe.

### SUMMARY OF THE INVENTION

Therefore, an object of the present invention is to provide an SOI-type semiconductor device, in which the aforesaid void-production problem can be resolved.

Another object of the present invention is to provide an SOI-type semiconductor device, in which both the aforesaid void-production problem and the aforesaid trench-width problem can be resolved.

Yet another object of the present invention is to provide a production method for manufacturing such an SOI-type semiconductor device.

In accordance with a first aspect of the present invention, there is provided a silicon-on-insulator (SOI)-type semiconductor device comprising a silicon substrate, and a buried silicon dioxide layer produced in the silicon substrate. An area of the silicon substrate, which is sited above the buried silicon dioxide layer, is defined as an SOI area, and the remaining area is defined as a non-SOI area. A peripheral edge portion of the buried silicon dioxide layer is formed as a swelling edge portion. The SOI-type semiconductor device further comprises a first field-isolation layer formed at the SOI area along the swelling edge portion of the buried silicon dioxide layer, and a second field-isolation layer formed at the non-SOI area along the swelling edge portion of the buried silicon dioxide layer.

Each of the first and second field-isolation layers is dimensioned such that voids are prevented from being produced therein.

The formation of the first and second field-isolation layers is carried out such that an annular or rectangular region is defined therebetween. The annular or rectangular region is dimensioned such that the swelling edge portion of the buried silicon dioxide layer is included therein, Also, the annular or rectangular region is dimensioned such that crystalline defects, caused by the swelling edge portion of the buried silicon dioxide layer, are included therein. The annular or rectangular region may be produced as an impurity-dosage region.

The first field-isolation layer may have a depth reaching an upper surface of the buried silicon dioxide layer. The second field-isolation layer may have a depth which is larger than that of the first field-isolation layer.

There may be at least one element-isolation layer formed in the SOI area of the silicon substrate. Also, there may be at least one element-isolation layer formed in the non-SOI area of the silicon substrate.

In accordance with a second aspect of the present invention, there is provided a production method for manufacturing a silicon-on-insulator (SOI)-type semiconductor, which method comprises the steps of: preparing a silicon substrate; producing a buried silicon dioxide layer in the silicon substrate, an area of the silicon substrate, which is sited above the buried silicon dioxide layer, being defined as an SOI area, the remaining area being defined as a non-SOI area, a peripheral edge portion of the buried silicon dioxide layer being formed as a swelling edge portion; forming a first field-isolation layer at the SOI area along the swelling edge portion of the buried silicon dioxide layer; and forming a second field-isolation layer at the non-SOI area along the swelling edge portion of the buried silicon dioxide layer.

In this production method, the formation of the first field-isolation layer and the formation of the second field-isolation layer may be simultaneously carried out. On the other hand, the formation of the first field-isolation layer and the formation of the second field-isolation layer may be independent from each other.

At least one element-isolation layer may be formed in the SOI area of the silicon substrate in synchronization with the formation of the first field-isolation layer. Also, at least one element-isolation layer may be formed in the non-SOI area of the silicon substrate in synchronization with the formation of the second field-isolation layer.

### BRIEF DESCRIPTION OF THE DRAWINGS

The above objects and other objects will be more clearly understood from the description set forth below, with reference to the accompanying drawings, wherein:

FIG. 1 is a partial cross-sectional view of a silicon substrate used in a first prior art silicon-on-insulator (SOI)-type semiconductor device;

FIG. 2 is a partial cross-sectional view, similar to FIG. 1, taken along the II-II line of FIG. 3, with an element-isolation layer being formed in the silicon substrate by using a shallow-trench isolation (STI) method;

FIG. 3 is a plan view of the silicon substrate shown in FIG. 2;

FIG. 4 is a cross-sectional view taken along the IV-IV line of FIG. 3;

FIG. 5 is a plan view of a silicon substrate used in a second prior art SOI-type semiconductor device;

FIG. 6 is a cross-sectional view taken along the VI-VI line of FIG. 5;

FIG. 7A is a partial cross-sectional view of a silicon substrate, showing a first representative step of a first embodiment of a production method process for manufacturing an SOI-type semiconductor device according to the present invention;

FIG. 7B is a partial cross-sectional view, similar to FIG. 7A, showing a second representative step of the first embodiment of the production method process according to the present invention;

FIG. 7C is a partial cross-sectional view, similar to FIG. 7B, showing a third representative step of the first embodiment of the production method process according to the present invention;

FIG. 7D is a partial cross-sectional view, similar to FIG. 7C, showing a fourth representative step of the first embodiment of the production method process according to the present invention;

FIG. 7E is a partial cross-sectional view, similar to FIG. 7D, showing a fifth representative step of the first embodiment of the production method process according to the present invention;

FIG. 7F is a partial cross-sectional view, similar to FIG. 7E, showing a sixth representative step of the first embodiment of the production method process according to the present invention;

FIG. 7G is a partial cross-sectional view, similar to FIG. 7F, showing a seventh representative step of the first embodiment of the production method process according to the present invention;

FIG. 7H is a partial cross-sectional view, corresponding to FIG. 7G and taken along the H-H line of FIG. 8, showing an eighth representative step of the first embodiment of the production method process according to the present invention;

FIG. 8 is a plan view of the semiconductor substrate shown in FIG. 7H;

FIG. 9A is a partial cross-sectional view of a silicon substrate, showing a first representative step of a second embodiment of a production method process for manufacturing an SOI-type semiconductor device according to the present invention;

FIG. 9B is a partial cross-sectional view, similar to FIG. 9A, showing a second representative step of the second embodiment of the production method process according to the present invention;

FIG. 9C is a partial cross-sectional view, similar to FIG. 9B, showing a third representative step of the second embodiment of the production method process according to the present invention;

FIG. 9D is a partial cross-sectional view, similar to FIG. 9C, showing a fourth representative step of the second embodiment of the production method process according to the present invention;

FIG. 9E is a partial cross-sectional view, similar to FIG. 9D, showing a fifth representative step of the second embodiment of the production method process according to the present invention; and

FIG. 9F is a partial cross-sectional view, similar to FIG. 9E, showing a fifth representative step of the second embodiment of the production method process according to the present invention.

### DESCRIPTION OF THE PREFERRED EMBODIMENTS

Before descriptions of embodiments of the present invention, for better understanding of the present invention, a first prior art silicon-on-insulator (SOI)-type semiconductor device will be now explained with reference to FIGS. 1, 2, 3 and 4.

In FIG. 1, reference 10 indicates a silicon substrate used in the first prior art SOI-type semiconductor device, and the silicon substrate 10 has a buried silicon dioxide layer 12 produced therein. An area 14 of the silicon substrate 10, which is sited above the buried silicon dioxide layer 12, is defined as an SOI area 14, and the remaining area 16 is defined as a non-SOI area.

When the production of the buried dioxide layer 12 is carried out by using a separation-by-implanted-oxygen (SIMOX) method, a peripheral edge portion of the buried silicon dioxide layer 12 swells to become thicker, as shown in FIG. 1.

In particular, in the SIMOX method, oxygen ions (O⁺) are implanted in the silicon substrate 10, so that the oxygen ions (O⁺) reach a given depth measured from the surface of the silicon substrate 10, and then the silicon substrate 10 is subjected to an annealing process in which the implanted oxygen ions (O⁺) react with silicon atoms in the silicon substrate 10 to thereby produce the buried silicon dioxide layer 12, resulting in the swelling of the peripheral edge portion of the buried silicon dioxide layer 12.

The swelling of the peripheral edge portion of the buried silicon dioxide layer 12 may cause crystalline defects in the silicon substrate 10 in the vicinity of the swelling edge portion. Note, in FIG. 1, one of the crystalline defects is symbolically and conceptually represented as a thick bar segment 18. When the crystalline defects 18 are left in the silicon substrate 10, they may cause a leakage of current in the SOI-type semiconductor device.

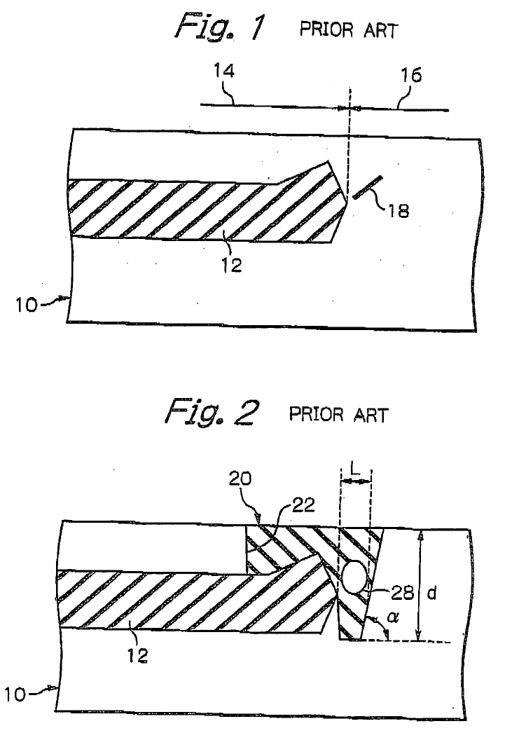

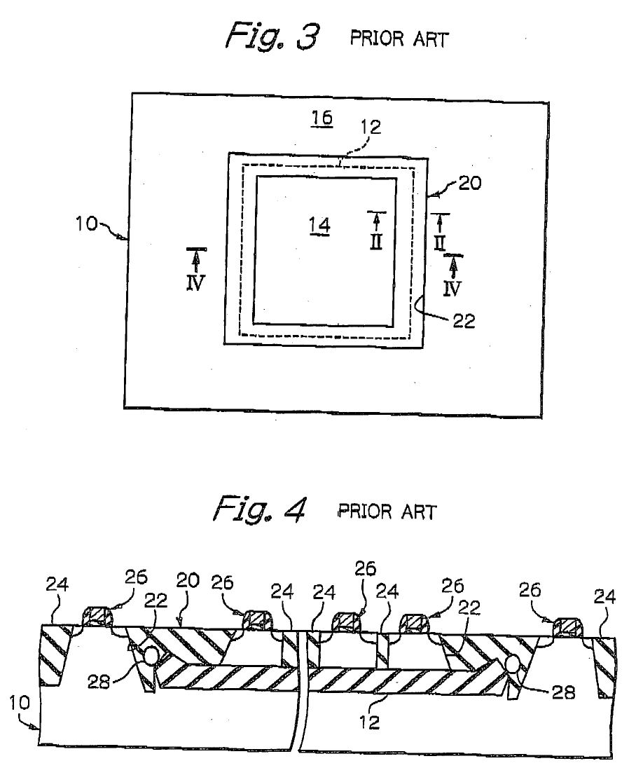

Therefore, conventionally, as shown in FIGS. 2 and 3, a silicon dioxide layer 20 is formed as a field-isolation layer in the silicon substrate 10 along a boundary between the SOI area 14 and the non-SOI area 16, i.e. along the swelling edge portion of the buried silicon dioxide layer 12), by using a shallow-trench isolation (STI) method, so that the crystalline defects 18 are eliminated from the silicon substrate 10.

In particular, first, a trench 22 is formed along the swelling edge portion of the buried silicon dioxide layer 12 by using a photolithography process and a dry etching process, to thereby eliminate the crystalline defects 18 from the silicon substrate 10. Then, the silicon substrate 10 is subjected to a chemical vapor deposition (CVD) process so that the trench 22 is filled with silicon dioxide, with a redundant silicon dioxide layer being formed on the surface of the silicon substrate 10. Subsequently, the redundant silicon dioxide layer is removed from the surface of the silicon substrate 10 by using a chemical mechanical polishing (CMP) process, resulting in the formation of the field-isolation layer 20, as shown in FIGS. 2 and 3. In short, the SOI area 14 is surrounded by the field-isolation layer 20 so as to be isolated from the non-SOI area 16.

Note, although not illustrated in FIGS. 2 and 3 to avoid complexity of illustration, when the formation of the field-isolation layer 20 is carried out, a plurality of element-isolation layers 24 are simultaneously formed in both the SOI area 14 and the non-SOI area 16 on the silicon substrate 10, as shown in FIG. 4.

After the formation of the field-isolation layer 20 and the element-isolation layers 24, various electronic elements, such as MOS transistors, capacitors, resistors and so on, are produced in an area on the silicon substrate 10, which is surrounded by each of the element-isolation layers 24. Note, in FIG. 4, only the MOS transistors among the various electronic elements are representatively shown, as indicated by reference 26. Also, note that the various electronic elements are omitted from FIGS. 2 and 3 to avoid complexity of illustration.

As stated above, according to the first prior art SOI-type semiconductor device, it is possible to eliminate the crystalline defects 18 from the silicon substrate 10 due to the formation of the field-isolation layer 20.

Nevertheless, according to research performed by the inventors, it was found that voids are apt to be produced in the field-isolation layer 20 in the vicinity of the swelling edge portion of the buried silicon oxide layer 12 when a distance between the inner wall face of the trench 22 and the swelling edge portion of the buried silicon oxide layer 12 is too small. Note, in FIGS. 2 and 4, the voids are symbolically and conceptually represented as an open oval circle 28.

In particular, in the research of the inventors, samples of SOI-type semiconductor devices were produced. In these samples, three dimensions d, α and L were defined as shown in FIG. 4. Namely, the dimension d represents a depth of a trench (22) for forming a field-isolation layer (20); the dimension a represents a taper angle α of the outer side wall face of the filed-isolation layer (22); and the dimension L represents a distance between an inner wall face of the trench (22) and a swelling edge portion of a buried silicon oxide layer (12). The depth d was 280 nm, and the taper angle α was 85 degrees. On the other hand, the distance L was varied among the samples.

In a case where the distance L was less than 140 nm, voids (28) were produced in the field-isolation layer (20) in the vicinity of the swelling edge portion of the buried silicon oxide layer (12). As for the reason why the voids (28) were produced, it is presumed that the trench (22) cannot be homogeneously filled with silicon dioxide in a CVD process, due to the swelling edge portion of the buried silicon dioxide layer (12). Of course, the production of the voids in the field-isolation layer (20) should be avoided because the existence of voids results in deterioration in performance of the SOI-type semiconductor device.

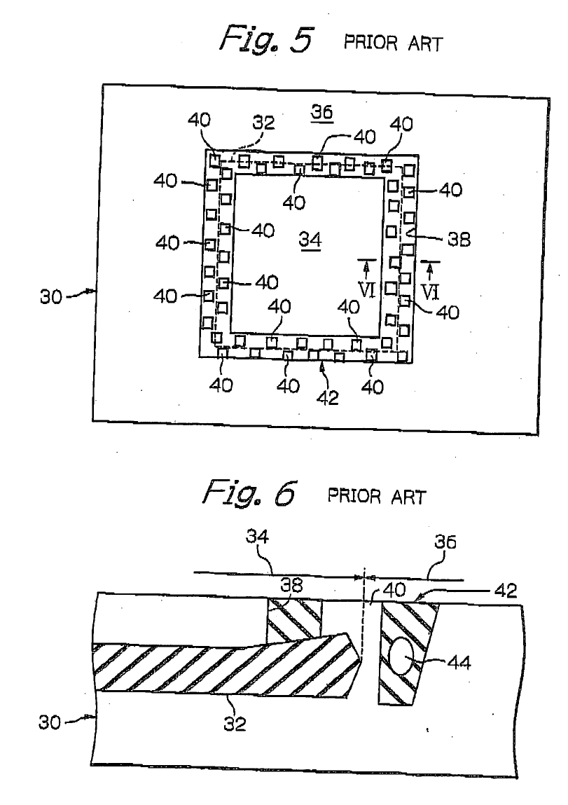

FIGS. 5 and 6 show a silicon substrate used in a second prior art SOI-type semiconductor device.

In FIGS. 5 and 6, the silicon substrate is generally indicated by reference 30. The silicon substrate 30 has a buried silicon dioxide layer 32 produced by using a SIMOX method, and an SOI area 34 and a non-SOI area 36 are defined in the silicon substrate 30 due to the production of the buried silicon dioxide layer 32. Similar to the first prior art SOI-type semiconductor device, when the production of the buried dioxide layer 32 is carried out by using the SIMOX method, a peripheral edge portion of the buried silicon dioxide layer 32 swells to become thicker, as shown in FIG. 6. The swelling of the peripheral edge portion of the buried silicon dioxide layer 12 may cause crystalline defects in the silicon substrate 30 in the vicinity of the swelling edge portion.

Similar to the first prior art SOI-type semiconductor device, in the second prior art SOI-type semiconductor device, although a trench 38 is formed in the semiconductor substrate 30 along a boundary between the SOI area 34 and the non-SOI area 36, i.e. along the swelling edge portion of the buried silicon dioxide layer 32, by using a STI method, to thereby eliminate the crystalline defects, the formation of the trench 38 is carried out such that a plurality of dummy regions 40 are discretely defined in the trench 38. Namely, the trench 38 is formed in the silicon substrate 30 such that a portion of the material forming the silicon substrate 30 is left as a corresponding dummy region.

After the formation of the trench 38 is completed, the silicon substrate 30 is subjected to a CVD process so that the trench 38 is filled with silicon dioxide, with a redundant silicon dioxide layer being formed on the surface of the silicon substrate 30. Then, the redundant silicon dioxide layer is removed from the surface of the silicon substrate 30 by using a CMP process, resulting in the formation of a field-isolation layer 42, as shown in FIGS. 5 and 6. In short, the SOI area 34 is surrounded by the field-isolation layer 42 so as to be isolated from the non-SOI area 36.

Note, although not illustrated in FIGS. 5 and 6 to avoid complexity of illustration, when the formation of the field-isolation layer 42 carried out, a plurality of element-isolation layers are simultaneously formed in both the SOI area 34 and the non-SOI area 36 on the silicon substrate 30.

In the above-mentioned first prior art SOI-type semiconductor device, during the CMP process, offsets may be formed at boundaries between the surface of the field-isolation layer 20 and both the SOI areas 14 and 16 on the silicon substrate 10, because the field-isolation layer 20 exhibits a polishing rate which is different from that at both the SOI areas 14 and 36 on the silicon substrate 10.

On the contrary, according to the second prior art SOI-type semiconductor device, it is possible to mitigate formation of offsets at boundaries between the surface of the field-isolation layer 42 and both the SOI areas 34 and 36 on the silicon substrate 30, because the dummy regions 40 are discretely arranged in the field-isolation layer 42. Nevertheless, the dummy regions 40 may cause production of voids in the field-isolation layer 42 at narrow spaces between the inner side wall faces of the trench 38 and the side wall faces of the dummy regions 40. Note, in FIG. 6, one of the voids is symbolically and conceptually represented as an open oval circle 44.

On the other hand, in the above-mentioned first and second prior art SOI-type semiconductor devices, a width of the trenches 22 and 38 becomes somewhat wider than a predetermined width dimension.

In particular, each of the trenches 22 and 38 includes two trench sections; a first trench section is sited at the SOI area side; and a second trench section is sited at the non-SOI area side. During the aforesaid dry etching process, the formation of the first trench section is prematurely completed in comparison with the second trench section, because the second trench section is deeper than the first trench section. Although the dry etching process is referred to as an anisotropic etching process, in reality, the first trench section may be subjected to over-etching until the formation of the second trench section is completed. As a result, the width of the trenches 22 and 38 becomes somewhat wider than the predetermined width dimension. Of course, as miniaturization of SOI-type semiconductor devices is advanced, this problem becomes more severe.

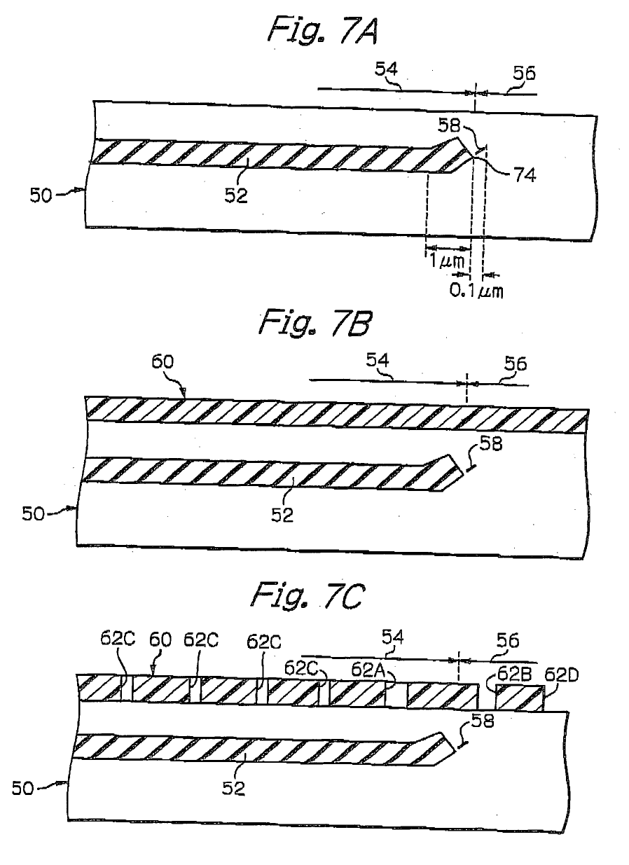

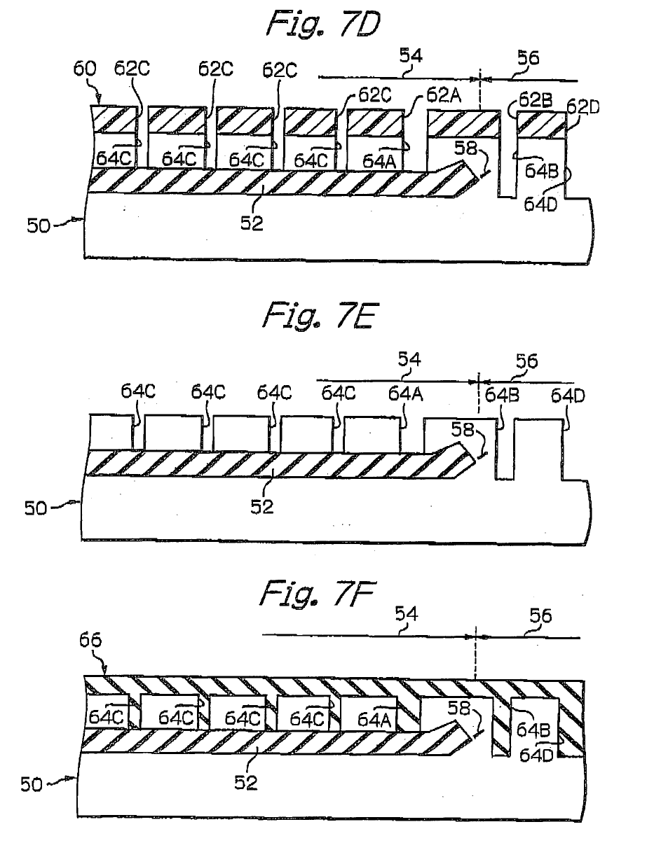

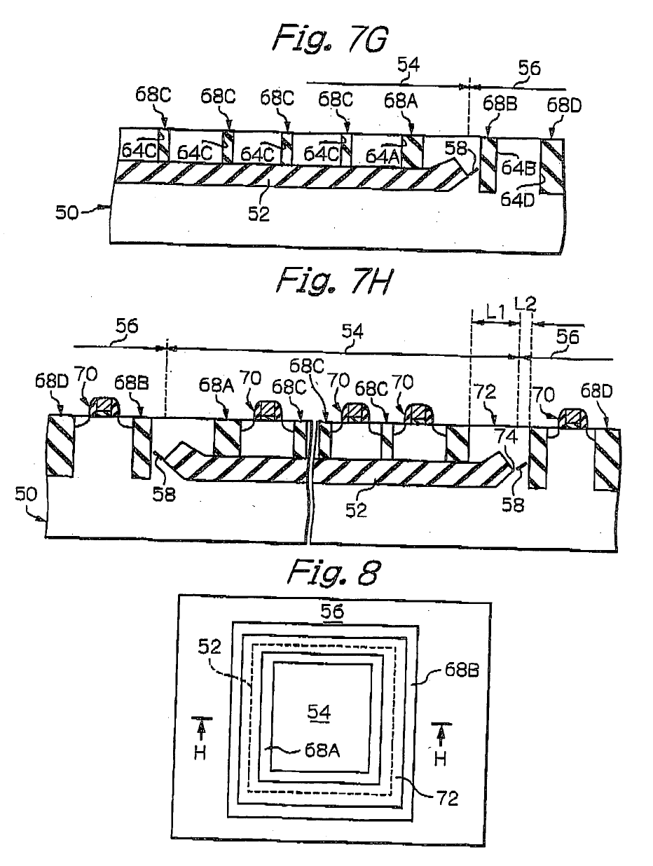

With reference to FIGS. 7A to 7H, a first embodiment of a production method for manufacturing an SOI-type semiconductor device according to the present invention will now be explained below.

First, as shown in FIG. 7A, a silicon substrate 50 is prepared, and a buried silicon dioxide layer 52 is produced in the silicon substrate 50 by using a SIMOX method. In this silicon substrate or OSI-substrate, an area of the silicon substrate 50, which is sited above the buried silicon dioxide layer 52, is defined as an SOI area 54, and the remaining area 56 is defined as a non-SOI area.

As already discussed, when the production of the buried silicon dioxide layer 52 is carried out by the SIMOX method, a peripheral edge portion of the buried silicon dioxide layer 52 swells to become thicker. The swelling of the peripheral edge portion of the buried silicon dioxide layer 52 may cause crystalline defects in the silicon substrate 50 in the vicinity of the swelling edge portion. Note, in FIG. 7A, one of the crystalline defects is symbolically and conceptually represented as a thick bar segment 58.

After the production of the buried silicon dioxide layer 52 is completed, as shown in FIG. 7B, a photoresist layer 60 is formed on the surface of the silicon substrate 50. Then, the photoresist layer 60 is patterned by using a photolithography process and an etching process, such that openings 62A, 62B, 62C and 62D are formed in the photoresist layer 56, as representatively shown in FIG. 7C.

As is apparent from the description mentioned later, the opening 62A is provided for forming a first field-isolation layer at the SOI area 54 along the swelling edge portion of the buried silicon dioxide layer 52; the opening 62B is provided for forming a second field-isolation layer at the non-SOI area 56 along the swelling edge portion of the buried silicon dioxide layer; the openings 62C are provided for forming element-isolation layers at the SOI area 54; and the opening 62D is provided for forming an element-isolation layer at the non-SOI area 56.

After the patterning of the photoresist layer 60 is completed, the silicon substrate 50 is subjected to a dry etching process by using the patterned photoresist layer 60 as a mask, so that respective trenches 64A, 64B, 64C and 64D, corresponding to the openings 62A, 62B, 62C and 62D, are formed in the silicon substrate 50, as shown in FIG. 7D. Then, the patterned photoresist layer 60 is removed from the surface of the silicon substrate 50 by using an ashing process, a wet peeling process or the like, as shown in FIG. 7E.

After the removal of the patterned photoresist layer 60 is completed, as shown in FIG. 7F, the silicon substrate 50 is subjected to a suitable CVD process so that the trenches 64A, 64B, 64C and 64D are filled with silicon dioxide, with a redundant silicon dioxide layer 66 being formed on the surface of the silicon substrate 50. Then, as shown in FIG. 7G, the redundant silicon dioxide layer 66 is removed from the surface of the silicon substrate 50 by using a CMP process.

As a result, the aforesaid first field-isolation layer, indicated by references 68A, which corresponds to the opening 62A, is formed in the trench 64A sited at the SOI area 54, and the aforesaid second field-isolation layer, indicated by references 68B, which corresponds to the opening 62B, is formed in the trench 64B sited at the non-SOI area 56. Similarly, the aforesaid element-isolation layers, indicated by reference 68C, which correspond to the openings 62C, are formed in the trenches 64C sited at the SOI area 54, and the aforesaid element-isolation layer, indicated by reference 68D, which corresponds to the opening 62D, is formed in the trenches 64D sited at the non-SOI area.

After the formation of the first and second field-isolation layers 68A and 68B and the element-isolation layers 68C and 68D is completed, various electronic elements, such as MOS transistors, capacitors, resistors and so on, are produced in an area on the silicon substrate 50, which is surrounded by each of the element-isolation layers 68C and 68D, as shown in FIG. 7H. Note, in FIG. 7H, only the MOS transistors among the various electronic elements are representatively shown, as indicated by references 70.

Referring to FIG. 8, the silicon substrate 50 shown in FIG. 7H is illustrated in a plan view. As is apparent from FIGS. 7H and 8, although an annular or rectangular region 72 including the crystalline defects 58 is defined between the first and second field-isolation layers 68A and 68B, no electronic element is formed in the annular or rectangular region 72. Thus, the SOI-type semiconductor device cannot be subjected to a negative influence due to the existence of the crystalline defects 58. Note that the various electronic elements are omitted from FIG. 8 to avoid complexity of illustration.

According research performed by the inventors, it was found that a crystalline defect 58 is located within a range of 0.1 μm, which is measured from an outermost end 74 of the swelling edge portion of the buried silicon dioxide layer 52, as shown in FIG. 7A. On the other hand, a width of the swelling edge portion is 1 μm, as shown in FIG. 7A.

Accordingly, it is preferable that the annular or rectangular region 72 has a width of more than 1.1 μm so that the swelling edge portion of the buried silicon dioxide layer 52 with the crystalline defect 58 is included in the annular or rectangular region 72. Namely, an outer wall face of the annular or rectangular region 72 should be separated from the outermost end 74 of the swelling edge portion by the distance of more than 0.1 μm, and an inner wall face of the annular or rectangular region 72 should be separated from the outermost end 74 of the swelling edge portion by the distance of more than 1 μm.

Also, when the width of the annular or rectangular region 72 is determined on a design of an SOI-type semiconductor device, it is necessary to consider accuracy of alignment in an exposure process for producing a buried silicon dioxide layer (52) using the SIMOX method, accuracy of alignment in an exposure process for forming a trench (64A, 64B, 64C, 64D), process fluctuation, and a designable minimum dimension of the trench (64A, 64B, 64C, 64D).

In particular, the distance L1 (FIG. 7H) between the inner wall face of the annular or rectangular region 72 and the outermost end 74 of the swelling edge portion can be determined as follows:
L1=AL1+AL2+PF+WD−MD (A)

Herein:
AL1 is the accuracy of alignment in the exposure process for producing the buried silicon dioxide layer using the SIMOX method;
AL2 is the accuracy of alignment in the exposure process for forming the trench;
PF is the process fluctuation;
WD is the width of the swelling edge portion of the buried silicon dioxide layer (1 μm); and
MD is the designable minimum dimension (1.4 μm).

Also, the distance L2 (FIG. 7H) between the outer wall face of the annular or rectangular region 72 and the outermost end 74 of the swelling edge portion can be determined as follows;
L2=AL1+AL2+PF (B)

Note, in the equation (B), the range of 0.1 μm, within which the crystalline defect (58) is located, is not taken into consideration, because the designable minimum dimension (MD=1.4 μm) is larger than the range of 0.1 μm.

For example, according to the 90 nm design rule,
AL1=0.06 μm
AL2=0.04 μm
PF=0.005 μm
WD=1.0 μm
MD=0.14 μm

Accordingly, L1 can be determined as 0.965 μm, using the equation (A), and L2 can be determined as 0.105 μm, using the equation (B).

Since impurity-implantation processes are performed during the manufacture of the SOI-type semiconductor device, the annular or rectangular region 72 is dosed with various impurities. Thus, the annular or rectangular region 72 is produced as an impurity-dosage region. The impurity-dosage region 72 has a first depth at the SOI area 54, and a second depth at the non-SOI area 66. The first depth is substantially equivalent to an 50I thickness which is defined as a distance between the surface of the silicon substrate 50 and the upper surface of the buried silicon dioxide layer 52. Usually, the SOI thickness falls within a range from 500 Å to 1500 Å. On the other hand, the second depth is defined as a well depth which may be approximately 4200 Å.

Note, the annular or rectangular region 72 may be masked whenever the impurity implantation process is performed, so that the annular or rectangular region 72 cannot be produced as the impurity-dosage region, if necessary.

The first field-isolation layer 64A should have a width of more than 140 nm (0.14 μm) so that voids cannot be produced in the first field-isolation layer 64A. Also, the first field-isolation layer 64A has a depth which is substantially equivalent to the aforesaid SOI thickness. Namely, the depth of the first field-isolation layer 64A falls within a range from 500 Å to 1500 Å.

Similar to the first field-isolation layer 64A, the second field-isolation layer 64B should have a width of more than 140 nm (0.14 μm) so that voids cannot be produced in the second field-isolation layer 64B. Also, the second field-isolation layer 64B has a depth which is larger than that of the first field-isolation layer 64A, and it may be approximately 2800 Å. Further, each of the outer side wall faces of the second field-isolation layer 64B may have a taper angle defined with the bottom face thereof, and the taper angle may be approximately 85 degrees.

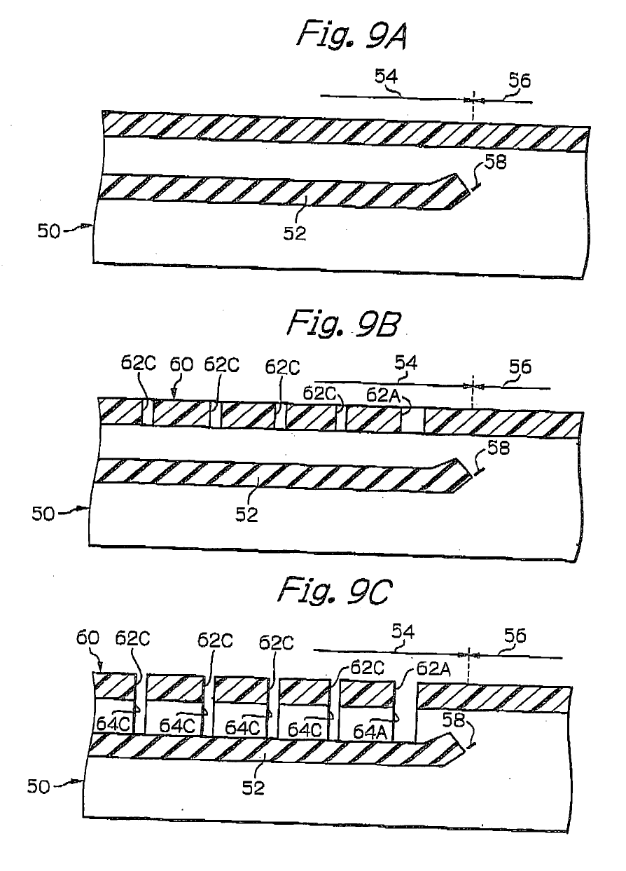

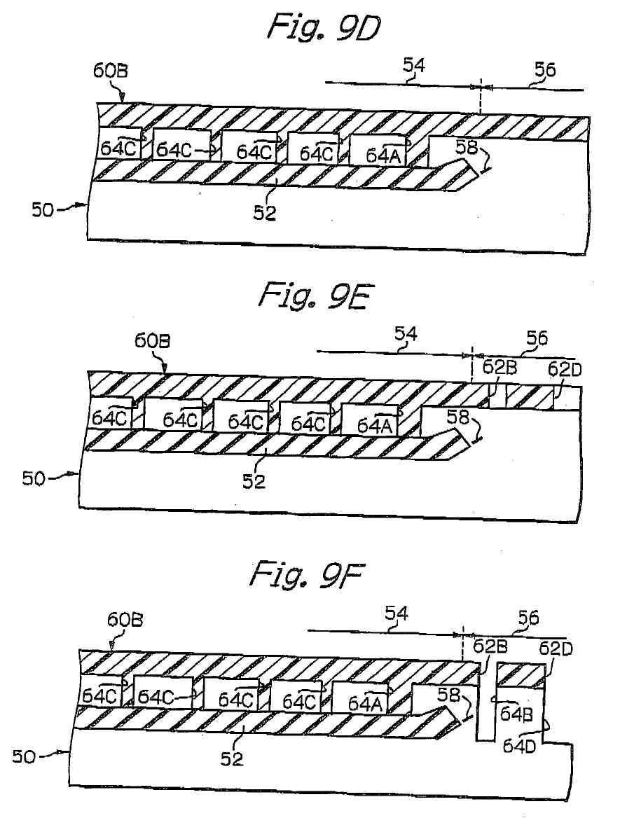

With reference to FIGS. 9A to 9E, a second embodiment of a production method for manufacturing an SOI-type semiconductor device according to the present invention will now be explained below. Note, in FIGS. 9A to 9E, the features similar to those of FIGS. 7A to 7E are indicated by the same references.

First, as shown in FIG. 9A, a silicon substrate 50 is prepared, and a buried silicon dioxide layer 52 is produced in the silicon substrate 50 by using a SIMOX method. In this silicon substrate or OSI-substrate, an area of the silicon substrate 50, which is sited above the buried silicon dioxide layer 52, is defined as an SOI area 54, and the remaining area 56 is defined as a non-SOI area.

Similar to the above-mentioned first embodiment, a peripheral edge portion of the buried silicon dioxide layer 52 swells thicker, and the swelling of the peripheral edge portion of the buried silicon dioxide layer 52 may cause crystalline defects in the silicon substrate 50 in the vicinity of the swelling edge portion. Note, in FIG. 8A, one of the crystalline defects is symbolically and conceptually represented as a thick bar segment 58.

After the production of the buried silicon dioxide layer 52 is completed, a photoresist layer 60A is formed on the surface of the silicon substrate 50, as shown in FIG. 9A. Then, the photoresist layer 60A is patterned by using a photolithography process and an etching process, such that openings 62A and 62C are formed in the photoresist layer 60A, as representatively shown in FIG. 9B.

The opening 62A is provided for forming a first field-isolation layer at the SOI area 54 along the swelling edge portion of the buried silicon dioxide layer 52, and the openings 62C are provided for forming element-isolation layers at the SOI area 54.

After the patterning of the photoresist layer 60A is completed, the silicon substrate 50 is subjected to a dry etching process by using the patterned photoresist layer 60A as a mask, so that respective trenches 64A and 64C, corresponding to the openings 62A and 62C, are formed in the silicon substrate 50, as shown FIG. 9C. Then, the patterned photoresist layer 60A is removed from the surface of the silicon substrate 50 by using an ashing process, a wet peeling process or the like.

After the removal of the photoresist layer 60A is completed, a photoresist layer 60B is again formed on the surface of the silicon substrate 50, as shown in FIG. 9D. Then, the photoresist layer 60B is patterned by using a photolithography process and an etching process, such that openings 62B and 62D are formed in the photoresist layer 60B, as representatively shown in FIG. 9E.

The opening 62B is provided for forming a second field-isolation layer at the non-SOI area 56 along the swelling edge portion of the buried silicon dioxide layer 52, and the opening 62D is provided for forming an element-isolation layer at the non-SOI area 56.

After the patterning of the photoresist layer 60B is completed, the silicon substrate 50 is subjected to a dry etching process by using the patterned photoresist layer 60B as a mask, so that respective trenches 64B and 64D, corresponding to the openings 62A and 62C, are formed in the silicon substrate 50, as shown FIG. 9F. Then, the patterned photoresist layer GOB is removed from the surface of the silicon substrate 50 by using an ashing process, a wet peeling process or the like.

The silicon substrate 50, from which the photoresist layer 60B is removed, is substantially equivalent to that shown in FIG. 7E. Thus, by processing the silicon substrate 50 in substantially the same manner as explained with reference to FIG. 7F to 7H, it is possible to obtain the SOI-type semiconductor device, as shown in FIGS. 7H and 8

According to the second embodiment of the present invention, since the formation of the trenches 64A and 64C at the SOI area is independent from the formation of the trenches 64B and 64D at the non-SOI area, each of the trenches 64A, 74B, 64C and 64D can have a proper dimension. Namely, the second embodiment of the present invention is free from the above-mentioned trench-width problem.

Finally, it will be understood by those skilled in the art that the foregoing description is of preferred embodiments of the methods and devices, and that various changes and modifications may be made to the present invention without departing from the spirit and scope thereof.

1. A silicon-on-insulator (SOI)-type semiconductor device comprising:
a silicon substrate;
a buried silicon dioxide layer produced in said silicon substrate, an area of said silicon substrate, which is sited above said buried silicon dioxide layer, being defined as an SOI area, the remaining area being defined as a non-SOI area, a peripheral edge portion of said buried silicon dioxide layer being formed as a swelling edge portion;
a first field-isolation layer formed at said SOI area along the swelling edge portion of said buried silicon dioxide layer; and
a second field-isolation layer formed at said non-SOI area along the swelling edge portion of said buried silicon dioxide layer.

2. The SOI-type semiconductor device as set forth in claim 1, wherein each of the said first and second field-isolation layers is dimensioned such that voids are prevented from being produced therein.

3. The SOI-type semiconductor device as set forth in claim 1, wherein the formation of said first and second field-isolation layers is carried out such that an annular or rectangular region is defined therebetween.

4. The SOI-type semiconductor device as set forth in claim 2, wherein said annular or rectangular region is dimensioned such that the swelling edge portion of said buried silicon dioxide layer is included therein

5. The SOI-type semiconductor device as set forth in claim 2, wherein said annular or rectangular region is dimensioned such that crystalline defects, caused by the swelling edge portion of said buried silicon dioxide layer, are included therein.

6. The SOI-type semiconductor device as set forth in claim 2, wherein said annular or rectangular region is produced as an impurity-dosage region.

7. The SOI-type semiconductor device as set forth in claim 1, wherein said first field-isolation layer has a depth reaching an upper surface of said buried silicon dioxide layer.

8. The SOI-type semiconductor device as set forth in claim 7, wherein said second field-isolation layer has a depth which is larger than that of said first field-isolation layer.

9. The SOI-type semiconductor device as set forth in claim 1, wherein there is at least one element-isolation layer formed in the SOI area of said silicon substrate.

10. The SOI-type semiconductor device as set forth in claim 9, wherein there is at least one element-isolation layer formed in the non-SOI area of said silicon substrate.

11. A production method that manufactures a silicon-on-insulator (SOI)-type semiconductor, which method comprises:
preparing a silicon substrate;
producing a buried silicon dioxide layer in said silicon substrate, an area of said silicon substrate, which is sited above said buried silicon dioxide layer, being defined as an SOI area, the remaining area being defined as a non-SOI area, a peripheral edge portion of said buried silicon dioxide layer being formed as a swelling edge portion;
forming a first field-isolation layer at said SOI area along the swelling edge portion of said buried silicon dioxide layer; and
forming a second field-isolation layer at said non-SOI area along the swelling edge portion of said buried silicon dioxide layer.

12. The production method as set forth in claim 11, wherein the formation of said first field-isolation layer and the formation of said second field-isolation layer are simultaneously carried out.

13. The production method as set forth in claim 11, wherein the formation of said first field-isolation layer and the formation of said second field-isolation layer are independent from each other.

14. The production method as set forth in claim 11, wherein each of the said first and second field-isolation layers is dimensioned such that voids are prevented from being produced therein.

15. The production method as set forth in claim 11, wherein the formation of said first and second field-isolation layers is carried out such that an annular or rectangular region is defined therebetween.

16. The production method as set forth in claim 15, wherein said annular or rectangular region is dimensioned such that the swelling edge portion of said buried silicon dioxide layer is included therein

17. The production method as set forth in claim 15, wherein, wherein said annular or rectangular region is dimensioned such that crystalline defects, caused by the swelling edge portion of said buried silicon dioxide layer, are included therein.

18. The production method as set forth in claim 15, wherein said annular or rectangular region is produced as an impurity-dosage region.

19. The production method as set forth in claim 11, wherein, said first field-isolation layer has a depth reaching an upper surface of said buried silicon dioxide layer.

20. The production method as set forth in claim 19, wherein said second field-isolation layer has a depth which is larger than that of said first field-isolation layer.

21. The production method as set forth in claim 11, wherein at least one element-isolation layer is formed in the SOI area of said silicon substrate in synchronization with the formation of said first field-isolation layer.

22. The production method as set forth in claim 11, wherein at least one element-isolation layer is formed in the non-SOI area of said silicon substrate in synchronization with the formation of said second field-isolation layer.
